(19) United States
(12) Patent Application Publication
(10) Pub. No.: US 2026/0123559 A1
(43) Pub. Date: Apr. 30, 2026

(54) LOW-TEMPERATURE HYBRID BONDING METHOD AND HYBRID BONDING ASSEMBLY ACCORDINGLY

(71) Applicant: FOUNDATION FOR RESEARCH AND BUSINESS, SEOUL NATIONAL UNIVERSITY OF SCIENCE AND TECHNOLOGY, Seoul (KR)

(72) Inventors: Sarah Eunkyung KIM, Seoul (KR); Dong Myeong LEE, Seoul (KR); Hoo Gwan LEE, Seoul (KR)

(73) Assignee: FOUNDATION FOR RESEARCH AND BUSINESS, SEOUL NATIONAL UNIVERSITY OF SCIENCE AND TECHNOLOGY, Seoul (KR)

(21) Appl. No.: 19/365,396

(22) Filed: Oct. 22, 2025

(30) Foreign Application Priority Data
Oct. 24, 2024 (KR) 10-2024-0146655

(51) Int. Cl. H01L 23/00

(52) U.S. Cl. CPC H10W 99/00; H10W 80/016; H10W 80/312; H10W 80/327

(57) ABSTRACT

A low-temperature hybrid bonding method includes a pre-treatment step of plasma-treating surfaces of first and second objects to be bonded, and a bonding step of aligning the first and second objects to be bonded and annealing them to form a bond between the first object to be bonded and the second object to be bonded through thermal expansion, wherein the first and second objects to be bonded comprise a hybrid bonding layer comprising copper and a dielectric, and the pre-treatment step is performed by treating with plasma using a hydrocarbon-based gas (CₓH_{y}, where x and y are natural numbers).

### CROSS-REFERENCE TO RELATED APPLICATION

This application claims priority to Korean Patent Application No. 10-2024-0146655, filed on Oct. 24, 2024 in the Korean Intellectual Property Office, the disclosure of which is incorporated herein by reference.

### STATEMENT OF SPONSORED RESEARCH OR DEVELOPMENT

This work was supported by K-CHIPS (Korea Collaborative & High-tech Initiative for Prospective Semiconductor Research) grant (RS-2023-00236091, 23035-45FC) funded by the Ministry of Trade. Industry & Energy (MOTIE, Korea): Hybrid bonding technologies for 3D package interconnect

This work was supported by the National Research Foundation of Korea (NRF) grant (RS-2025-25442278) funded by the Korea government (MSIT, Korea): Development of core technologies of 3D stack bonder and ultra-high resolution composite inspection equipment for ultra-high density hybrid bonding

### BACKGROUND OF THE DISCLOSURE

### Field of the Disclosure

The present disclosure relates to a low-temperature hybrid bonding method and a hybrid bonding assembly thereof, and more particularly, to a technology for activating a dielectric and copper in a single process through a plasma treatment method.

### Description of the Related Art

With the trend toward miniaturization and higher functionality of electronic products, packaging technology for semiconductor devices is continuously advancing, and the technological paradigm is significantly changing due to the ultra-miniaturization of semiconductor devices, a rapid increase in the number of input/output terminals, fine pitches between terminals, and a surge in the number of stacks.

In particular, there is a demand for a single package with high connectivity and bandwidth, low latency, and low power, as well as multi-functionality, for which 2.5D or 3D packaging technologies are being utilized.

3D packaging technology generally consists of Through-Si Via (TSV) formation, Si wafer grinding, and wafer-to-wafer or chip-to-chip bonding processes. Products using this technology include CMOS Image Sensors (CIS) and High Bandwidth Memory (HBM), and products with stacked heterogeneous devices using Intel's Foveros and TSMC's SoIC technologies have begun to appear.

The technology for packaging such devices is necessarily implemented through a bonding process between semiconductor devices or between a semiconductor device and a substrate. However, conventional packaging technologies using bonding processes such as solder or micro-bumps are not keeping pace with the scaling speed of devices, and although copper is required as a bonding material for high-performance, high-integration devices, the high process temperature for copper bonding presents limitations for stacking various types of devices.

As such, regarding the device bonding process, the need for fine-pitch bonding and stack bonding is continuously increasing. Simultaneously, there is a persistent demand for bonding materials with excellent electrical and thermal properties and cost-effectiveness, as well as a need for low-temperature processes.

Furthermore, with the increasing demand for high-performance, high-functionality devices, copper/dielectric hybrid bonding is emerging as critically important in next-generation stacked packaging structures.

In copper/dielectric hybrid bonding, pre-treatment of the copper and dielectric surfaces before bonding is essential. For the copper surface, a process to remove surface contamination and oxides and to activate the copper surface is necessary. For the dielectric surface, a surface treatment to enhance its hydrophilicity is required.

The most commonly used pre-treatment process for copper and dielectric surface treatment is plasma-based, with representative plasma gases including argon (Ar), nitrogen (N₂), oxygen (O₂), or forming gas.

Forming gas is a representative reducing gas, but its low hydrogen ratio (about 5%) leads to incomplete removal of metal oxides. To enhance the reactivity for removing metal oxides, the process temperature must be increased, which raises issues of disadvantages and stability.

Moreover, forming gas may cause compatibility issues with CMOS manufacturing processes, highlighting the need to explore alternative treatments that provide stable oxide removal and surface activation.

### RELATED ART DOCUMENTS

### Patent Documents

Korean Patent No. 10-2099430, “Low Temperature Cu Bonding method and Low Temperature Cu Bonding package”
Japanese Patent No. JP 6285213 B2, “METHOD OF CLEANING PLASMA PROCESSING APPARATUS”

### Non-Patent Documents

(Non-Patent Document 0001) “Direct Copper-Copper Wafer Bonding with Ar/N₂ Plasma Activation”, IEEE (2015)
(Non-Patent Document 0002) “Surface modification of polyethylene using argon and argon/methane DBD atmospheric pressure plasma jet”, 2023 Phys. Scr. 98 085608

### SUMMARY OF THE DISCLOSURE

Therefore, the present disclosure has been made in view of the above problems, and it is an object of the present disclosure to provide a hybrid bonding method that allows for an in-air bonding process and exhibits good bonding properties at a low process temperature without using additional materials for bonding, such as a bonding paste.

It is another object of the present disclosure to provide a hybrid bonding method that can improve electrical and thermal conductivity characteristics.

It is still another object of the present disclosure to provide a hybrid bonding method that can exhibit excellent bonding properties in the bonding of objects that include a hybrid bonding layer including copper and a dielectric.

It is still another object of the present disclosure to provide a hybrid bonding method that can perform bonding with a simplified process, compared to conventional bonding methods for hybrid bonding involving a copper and dielectric layer.

It is yet another object of the present disclosure to provide a hybrid bonding method wherein the pre-treatment of the hybrid bonding layer, including copper and a dielectric, can be performed at room temperature.

In accordance with an aspect of the present disclosure, the above and other objects can be accomplished by the provision of a low-temperature hybrid bonding method, including: a pre-treatment step of plasma-treating surfaces of first and second objects to be bonded; and a bonding step of aligning the first and second objects to be bonded and annealing them to form a bond between the first object to be bonded and the second object to be bonded through thermal expansion, wherein the first and second objects to be bonded include a hybrid bonding layer including copper and a dielectric, and the pre-treatment step is performed by treating with plasma using a hydrocarbon-based gas (CₓH_{y}, where x and y are natural numbers).

The hydrocarbon-based gas may be one selected from the group consisting of methane (CH₄), methylene (CH₂), acetylene (C₂H₂), ethylene (C₂H₄), and propylene (C₃H₆).

The pre-treatment step may reduce oxides formed on the surface of the copper included in the first and second objects to be bonded, and deposit a hydrogenated amorphous carbon layer (a-C:H layer) with a thickness of 2 to 10 nm on the copper surface to prevent immediate re-oxidation.

After the pre-treatment step, surface hydrophilicity of the first and second objects to be bonded may be increased, thereby improving interfacial bonding stability, and surface roughness of the first and second objects to be bonded may be reduced, forming a void-free bonding interface that enables uniform diffusion of the copper.

The hydrogenated amorphous carbon layer may prevent the formation of an oxide layer on the copper surface, thereby reducing an energy barrier required for the diffusion of copper atoms, and may be thermally decomposed during the bonding step to form a copper-copper metal contact surface, thereby enabling bonding to be performed at a temperature condition of 300° C. or below.

### BRIEF DESCRIPTION OF THE DRAWINGS

The above and other objects, features and other advantages of the present disclosure will be more clearly understood from the following detailed description taken in conjunction with the accompanying drawings, in which:

FIG. 1 is a flowchart illustrating a low-temperature hybrid bonding method according to an embodiment of the present disclosure;

FIG. 2 is a schematic diagram illustrating a formation step of first and second objects to be bonded, used in a low-temperature hybrid process according to an embodiment of the present disclosure:

FIG. 3A is a schematic diagram of the low-temperature hybrid bonding method according to an embodiment of the present disclosure:

FIG. 3B is a schematic diagram of a plasma treatment apparatus used in the low-temperature hybrid bonding method according to an embodiment of the present disclosure:

FIG. 4 is a schematic diagram illustrating chip-level dicing and bonding processes after plasma treatment:

FIG. 5 is a set of graphs illustrating the relationship between input variables and response indicators according to the Design of Experiment (DOE) and Response Surface Method (RSM) performed to optimize plasma treatment conditions according to an embodiment of the present disclosure:

FIGS. 6A to 8B illustrate the peak deconvolution results of C1s(a) and Cu₂p^{3/2}(b) for a non-plasma sample, Case 11, and Case 16, respectively:

FIGS. 9A to 9F are cross-sectional TEM images comparing the surface carbon layers of the non-plasma sample (Case 0; a, d), Case 11 (b, e), and Case 16 (c, f), and FIGS. 9G to 9I illustrate the FFT patterns of the non-plasma sample (Case 0), Case 11, and Case 16, respectively:

FIG. 10 is a graph comparing the resistivity of copper thin films according to the presence and conditions of plasma treatment; and

FIGS. 11A to 12C illustrate the line scanning results (a), a cross-sectional TEM image of the bonding interface (b), and the FFT analysis results of the bonding interface (c), for Cases 11 and 16, respectively:

FIG. 13 illustrates the Ar—CH₄ plasma treatment mechanism of the present disclosure.

### DETAILED DESCRIPTION OF THE DISCLOSURE

The present disclosure will now be described more fully with reference to the accompanying drawings and contents disclosed in the drawings. However, the present disclosure should not be construed as limited to the exemplary embodiments described herein.

The terms used in the present specification are used to explain a specific exemplary embodiment and not to limit the present inventive concept. Thus, the expression of singularity in the present specification includes the expression of plurality unless clearly specified otherwise in context. It will be further understood that the terms “comprise” and/or “comprising”, when used in this specification, specify the presence of stated components, steps, operations, and/or elements, but do not preclude the presence or addition of one or more other components, steps, operations, and/or elements thereof.

It should not be understood that arbitrary aspects or designs disclosed in “embodiments”, “examples”, “aspects”, etc. used in the specification are more satisfactory or advantageous than other aspects or designs.

In addition, the expression “or” means “inclusive or” rather than “exclusive or”. That is, unless otherwise mentioned or clearly inferred from context, the expression “x uses a or b” means any one of natural inclusive permutations.

In addition, as used in the description of the disclosure and the appended claims, the singular forms “a”, “an” and “the” are intended to include the plural forms as well, unless context clearly indicates otherwise.

In addition, when an element such as a layer, a film, a region, and a constituent is referred to as being “on” another element, the element can be directly on another element, or an intervening element can be present.

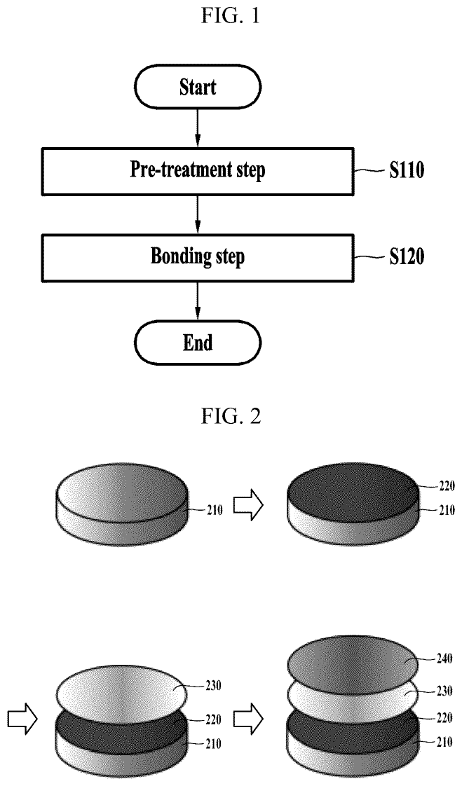

FIG. 1 is a flowchart illustrating a low-temperature hybrid bonding method according to an embodiment of the present disclosure.

Referring to FIG. 1, the low-temperature hybrid bonding method according to an embodiment of the present disclosure includes a pre-treatment step (S110) of plasma-treating the surfaces of a first object to be bonded and a second object to be bonded, and a bonding step (S120) of aligning and annealing the first and second objects to be bonded to form a bond between the first object to be bonded and the second to-be-bonded object through thermal expansion.

In the pre-treatment step (S110) of the low-temperature hybrid bonding method according to an embodiment of the present disclosure, plasma treatment may be used to clean contaminants from the copper surfaces included in the first and second objects to be bonded, reduce the oxides formed on the copper surfaces, and enhance the hydrophilicity of the surface of the dielectric included in the bonding layers of the first and second objects to be bonded, thereby activating the surfaces of the first and second objects to be bonded into a state conducive to adsorption.

In the low-temperature hybrid bonding method according to an embodiment of the present disclosure, the first and second objects to be bonded may have a structure including a substrate, a dielectric, and a copper thin film, and more specifically, may have a structure including a dielectric layer formed on a substrate and a copper thin film formed on or between the dielectric layer. As needed, a metal layer for adhesion and prevention of copper diffusion may be further included between the dielectric layer and the copper thin film.

In the pre-treatment step (S110) of the low-temperature hybrid bonding method according to an embodiment of the present disclosure, plasma treatment using a hydrocarbon-based gas (CxHy, where x and y are natural numbers) may be performed to clean and activate the surfaces of the first and second objects to be bonded.

More specifically, in the pre-treatment step (S110), copper oxides naturally formed on the surface of the copper thin film are reduced and removed by hydrogen radicals and ions generated by the plasma, and at the same time, a thin carbon layer (hydrogenated amorphous carbon layer, a-C:H) is formed on the surface of the copper thin film, which may suppress the re-oxidation of the copper surface during air exposure.

The copper thin film included in the first and second objects to be bonded naturally oxidizes upon air exposure, forming copper oxides on the surface. These copper oxides block metal-to-metal diffusion, which may cause defects at the bonding interface between the objects to be bonded during the bonding step (S120), resulting in degradation of the device's electrical and mechanical performance.

Therefore, in the low-temperature hybrid bonding method according to an embodiment of the present disclosure, immediate surface re-oxidation of the copper thin film may be prevented by removing the copper oxides on the copper surface through hydrocarbon-based plasma reduction and simultaneously forming a hydrogenated amorphous carbon layer on the copper thin film surface.

That is, the hydrogenated amorphous carbon layer maintains the copper thin film surface in an activated state without oxides even during the bonding step (S120), which reduces the energy barrier required for copper-copper diffusion, allowing the bonding process in the bonding step (S120) to be performed at a low temperature of 300° C. or below.

More specifically, the hydrogen component included in the hydrogenated amorphous carbon layer reduces residual oxide species to keep the copper thin film surface clean, and the amorphous structure with a mixture of sp² and sp³ bonds may alleviate interfacial stress with the copper lattice, inducing smooth copper diffusion at low temperatures.

Thus, in the low-temperature hybrid bonding method according to an embodiment of the present disclosure, the bonding process is performed at a low temperature of 300° C. or below, which is lower than existing bonding processes, and the hydrogenated amorphous carbon layer may be thermally decomposed and transformed during the bonding process to form a uniform bonding interface composed of copper-copper.

Before the pre-treatment step (S110) of the low-temperature hybrid bonding method according to an embodiment of the present disclosure, a formation step of the objects to be bonded may be further included. The formation step of the objects to be bonded will be described in detail with reference to the schematic diagram of FIG. 2.

FIG. 2 is a schematic diagram illustrating a formation step of the first and second objects to be bonded, used in the low-temperature hybrid process according to an embodiment of the present disclosure.

As shown in FIG. 2, the first and second objects to be bonded may include a dielectric layer 220 formed on a substrate 210, a metal layer 230 formed on the dielectric layer 220, and a copper thin film 240 formed on the metal layer 230, and metal wiring may be formed through a copper damascene process.

In the low-temperature hybrid bonding method according to an embodiment of the present disclosure, the substrate 210 serves as a support for a copper and dielectric layer, and may include one selected from the group consisting of silicon (Si), sapphire (Al₂O₃), quartz, or glass. Additionally, for application in flexible electronic devices, a polymer substrate such as polyimide may be used.

In the low-temperature hybrid bonding method according to an embodiment of the present disclosure, the substrate 210 may provide a stable bonding foundation in the low-temperature hybrid bonding process by offering mechanical stability, thermal properties, and surface flatness.

In the low-temperature hybrid bonding method according to an embodiment of the present disclosure, the dielectric layer 220 may provide insulation between copper, prevent electrical leakage at the bonding interface, and suppress the diffusion of copper. The dielectric layer 220 is deposited by a plasma-enhanced chemical vapor deposition (PECVD) method, and unnecessary portions may be removed by a photolithography process.

The dielectric layer 220 may be a silicon oxide film (SiO₂), a silicon nitride film (Si₃N₄), a silicon carbonitride film (SiCN), or a low-k dielectric (e.g., SiCOH, OSG), and materials usable for the dielectric layer 220 have excellent insulating properties and process compatibility, and may ensure bonding reliability with copper.

In the low-temperature hybrid bonding method according to an embodiment of the present disclosure, the copper thin film 240 forms the bonding layer of the object to be bonded and may be formed by a method such as sputtering, electroplating, or chemical vapor deposition (CVD). After the deposition of the copper thin film 240, protruding parts of the copper may be planarized through Chemical Mechanical Polishing (CMP).

In the low-temperature hybrid bonding method according to an embodiment of the present disclosure, a metal layer 230 may be further formed between the dielectric layer 220 and the copper thin film 240 for adhesion and diffusion prevention. The metal layer 230 may be deposited by a sputtering method, but the configuration of the present disclosure is not limited thereto.

The metal layer 230 may include any one of titanium (Ti), tantalum (Ta), tantalum nitride (TaN), titanium nitride (TiN), titanium tungsten (TiW), chromium (Cr), or ruthenium (Ru), and may improve the interfacial adhesion between the copper thin film 240 and the dielectric layer 220 and suppress the diffusion of copper into the dielectric.

In an embodiment of the present disclosure, the first and second objects to be bonded are formed with a structure including a dielectric layer 220 formed on a silicon substrate 210 by thermal oxidation, a metal layer 230 formed on the dielectric layer 220, and a copper thin film 240 deposited on the metal layer 230 by DC sputtering. By performing bonding between the objects to be bonded continuously within the sputtering equipment, process continuity may be ensured.

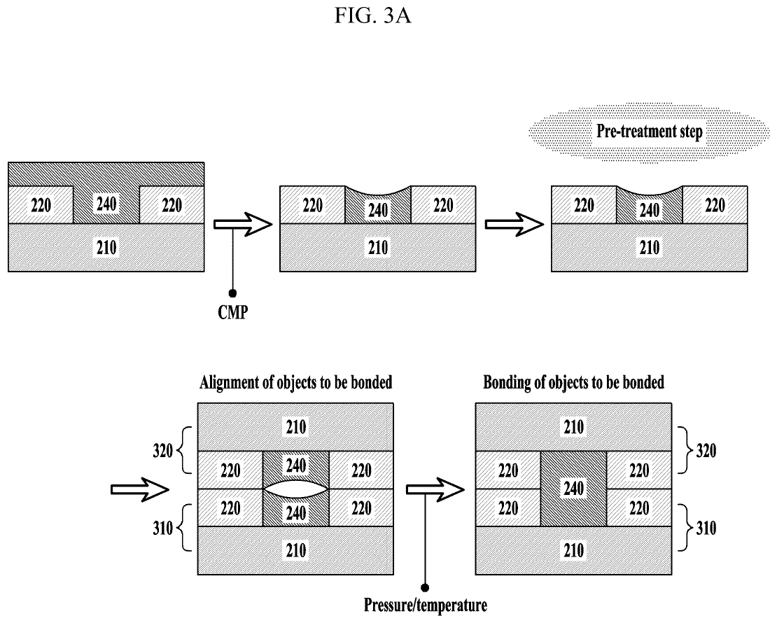

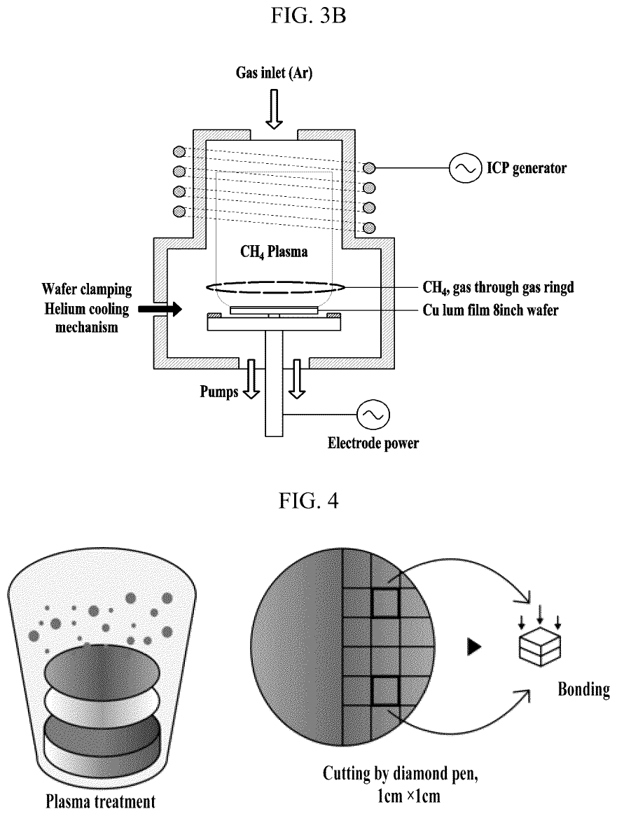

FIG. 3A is a schematic diagram of the low-temperature hybrid bonding method according to an embodiment of the present disclosure.

As shown in FIG. 3A, a first object to be bonded 310 and a second object to be bonded 320 include a hybrid bonding layer including a copper thin film 240 and a dielectric 220, and a Chemical Mechanical Polishing (CMP) process may be performed on the first and second objects to be bonded 310 and 320 before the pre-treatment step.

The CMP process is a process that polishes the surface by combining mechanical friction using a slurry and a pad with a chemical reaction. It removes protrusions on the metal and dielectric surfaces and reduces surface roughness, thereby securing flatness before bonding.

Furthermore, by processing the copper thin film and the dielectric layer through the CMP process so that they are exposed on the same plane, it is advantageous in suppressing the occurrence of interface defects or voids during the subsequent alignment and bonding process of the objects to be bonded. The CMP process may be performed by controlling conditions to minimize phenomena such as dishing or erosion due to excessive polishing.

In the pre-treatment step, the surface cleaning and activation of the copper thin film 240 and the dielectric 220 included in the first and second objects to be bonded 310 and 320 may be carried out through plasma treatment using a hydrocarbon-based gas (CₓH_{y}, where x and y are natural numbers).

More specifically, the plasma treatment using a hydrocarbon-based gas (CₓH_{y}, where x and y are natural numbers) reduces the copper oxides formed on the surface of the copper thin film 240 and deposits a hydrogenated amorphous carbon layer that protects the surface of the copper thin film 240, thereby preventing the re-oxidation of the copper thin film 240.

When the copper thin film 240 is exposed to air, it forms copper oxides such as Cu₂O, CuO, Cu(OH)₂, or CuCO₃. Through plasma treatment using an inert gas or forming gas, surface cleaning to remove copper oxides or any contaminants from the surface of the copper thin film 240 may be performed to activate the surface of the copper thin film 240.

For the reduction of oxides formed on the surface of the copper thin film 240, it is preferable to use hydrogen. The product of the hydrogen reduction reaction is water (H₂O), which may be easily removed without residue compared to using other reducing agents like CO or NH₃, thus there may be less concern about interfacial contamination.

Forming gas, a representative reducing gas, has a low hydrogen ratio (about 5%), leading to incomplete removal of metal oxides. A high process temperature is required to increase the removal rate of metal oxides, and there are gas stability issues, which necessitates the search for alternative treatments.

The low-temperature hybrid bonding method according to an embodiment of the present disclosure may more effectively remove metal oxides on the copper surface, compared to plasma treatment using conventionally used inert gases or forming gases, by performing plasma treatment with a hydrocarbon-based gas with high hydrogen content in the pre-treatment step.

Furthermore, the plasma treatment method using a hydrocarbon-based gas generates various reactive species, such as hydrogen radicals, hydrogen ions, or CHₓ radicals, in the plasma, which enhances the reactivity of the reduction reaction. Therefore, the pre-treatment process for the surfaces of the copper thin film 240 and the dielectric 220 may be performed at room temperature.

After the pre-treatment process of the low-temperature hybrid bonding method according to an embodiment of the present disclosure, the surface hydrophilicity of the first and second objects to be bonded 310 and 320 may be increased. Plasma treatment using a hydrocarbon-based gas generates hydrogen radicals (H·) and carbon radicals (C·, CHₓ, etc.). The hydrogen radicals reduce and remove the oxides present on the copper surface, and simultaneously, polar functional groups such as C—H, C—O, or —OH may be introduced on the surface, increasing the surface energy.

When the surface energy increases, the wettability of water molecules improves, which may decrease the contact angle and increase surface hydrophilicity. The enhancement of hydrophilicity due to the pre-treatment process may increase intermolecular attraction and van der Waals forces between interfaces during the subsequent bonding process, thereby improving initial adhesion stability and interfacial bonding stability.

After the pre-treatment process of the low-temperature hybrid bonding method according to an embodiment of the present disclosure, the surface roughness of the first and second objects to be bonded 310 and 320 may be reduced, allowing for the formation of a void-free bonding interface that enables uniform diffusion of copper.

High-energy ions or radicals generated by plasma treatment may physically etch protrusions on the surface of the copper thin film 240 to remove uneven features, and simultaneously, hydrogen radicals and hydrogen ions may reduce and remove oxides on the surface of the copper thin film 240 to smooth the surface.

That is, the surface roughness may be reduced and flatness may be improved by the physical and chemical actions of the plasma treatment. As the surface becomes flatter, the contact area between the two objects to be bonded increases during the bonding process, allowing for more uniform metal-to-metal diffusion, and a void-free bonding interface may be formed where no pores or discontinuities are formed within the bonding interface.

In the low-temperature hybrid bonding method according to an embodiment of the present disclosure, a thin carbon layer is deposited on the surfaces of the copper thin film 240 and the dielectric 220 due to plasma treatment with a hydrocarbon-based gas, and this deposited carbon layer may prevent the re-oxidation of the copper thin film 240 due to air exposure.

In the low-temperature hybrid bonding method according to an embodiment of the present disclosure, the carbon layer deposited by plasma treatment with a hydrocarbon-based gas may be a hydrogenated amorphous carbon layer, and the thickness of the hydrogenated amorphous carbon layer may be from 2 to 10 nm.

FIG. 3B is a schematic diagram of a plasma treatment apparatus used in the low-temperature hybrid bonding method according to an embodiment of the present disclosure. The schematic diagram of FIG. 3B illustrates an experiment involving plasma treatment using methane gas on an 8-inch wafer on which a copper thin film with a 1 μm thick was deposited.

As shown in FIG. 3B, a gas inlet for argon (Ar) gas is provided at the top of the plasma treatment apparatus to supply the gas for plasma formation, and in the center of the chamber, methane (CH₄) gas is injected through a gas ring to form a plasma together with the argon gas.

In the low-temperature hybrid bonding method according to an embodiment of the present disclosure, in addition to methane (CH₄) gas, a hydrocarbon-based gas (CₓH_{y}, where x and y are natural numbers) may be used for plasma treatment, and the hydrocarbon-based gas may be at least one selected from the group consisting of methane (CH₄), methylene (CH₂), acetylene (C₂H₂), ethylene (C₂H₄), and propylene (C₃H₆).

In one embodiment, plasma treatment using C₂H₄ gas may include the following steps to reduce copper oxides. However, this configuration is merely exemplary, and the configuration of the present disclosure is not limited thereto.

In plasma treatment using C₂H₄ gas, first, C₂H₄ gas may be ionized to generate various reactive species such as hydrogen radicals (H·), methyl radicals (CH₃·), ethyl radicals (C₂H₅·), and excited C₂H₄ molecules, along with free electrons in the plasma. Furthermore, as hydrogen (H) is continuously detached from various radicals present in the plasma, additional hydrogen radicals (H·) may be formed.

An inductively coupled plasma (ICP) generator located at the top of the plasma treatment apparatus applies an electromagnetic field to generate high-density plasma, and a lower electrode power supply may apply a bias to the electrode to accelerate ions in the plasma towards the substrate surface. A pump is connected to the bottom of the chamber to control the internal pressure in the range of several mTorr to several tens of mTorr, which may regulate plasma reactivity.

Inside the chamber, an 8-inch wafer with a deposited copper thin film (1 μm) is mounted, and the wafer may be secured by a clamping mechanism such as an electrostatic chuck (ESC) that electrically holds the wafer, a mechanical clamp that physically presses it, or a vacuum chuck that uses a vacuum.

Additionally, a helium cooling mechanism may be applied to the backside of the wafer to control the heat generated during plasma treatment, thereby preventing the wafer from overheating.

In particular, the highly reactive hydrogen radicals may react with the oxygen atoms of the copper oxides to form water (H₂O), thereby cleaning the copper surface.

Plasma treatment using C₂H₄ gas may not only reduce the oxides formed on the surface of the copper thin film 240 but may also deposit a thin carbon layer on the surface of the copper thin film 240 to form an anti-oxidation layer, i.e., passivation.

The low-temperature hybrid bonding method according to an embodiment of the present disclosure has the advantage that hybrid bonding is possible even in air, as a carbon layer that prevents oxidation is formed on the copper thin film 240.

Conventional pre-treatment processes for copper and dielectric surface treatment include oxygen plasma followed by steam treatment, argon plasma treatment followed by nitrogen plasma treatment, or argon plasma treatment followed by a hydrocarbon gas-based immersion process. However, most are performed in two steps, and no example of a single-step process performed at room temperature has been reported to date.

The low-temperature hybrid bonding method according to an embodiment of the present disclosure has the advantage that it may perform the surface cleaning, oxide removal, and activation treatment of the copper thin film and dielectric in a single process of plasma treatment using a hydrocarbon-based gas, and the process may be conducted under room temperature conditions.

The low-temperature hybrid bonding method according to an embodiment of the present disclosure may further include a wet treatment after the pre-treatment step, but it is optional, and low-temperature bonding is possible even without the wet treatment.

In the bonding step performed after the pre-treatment step, the plasma-treated objects to be bonded are placed adjacent to each other and then thermo-compressed, so that bonding may occur at the joint between the first and second objects to be bonded 310 and 320.

During thermo-compression in the bonding step, the carbon layer formed on the surface of the copper thin film 240 included in the first and second objects to be bonded 310 and 320 is removed, and bonding may occur at the joint between the first and second objects to be bonded 310 and 320.

Referring to FIGS. 3A and 3B, after the CMP process of the low-temperature hybrid bonding method according to an embodiment of the present disclosure, the height of the copper thin film 240 may be formed to be slightly lower than the height of the dielectric layer 220 surrounding the copper thin film 240. The phenomenon where the copper surface is formed slightly lower than the height of the surrounding oxide is called copper dishing.

Due to the structure where the height of the copper thin film 240 is lower, dielectric-to-dielectric bonding occurs first during bonding. Then, when heat is applied, the thermal expansion coefficient of copper is larger than that of the dielectric, so the gap between the two copper surfaces is filled by internal stress, and a strong bonding interface may be formed through mutual diffusion between the copper.

Controlling this dishing is very important for achieving a high-quality bonding interface. If the dishing is too shallow, the expansion of copper may cause excessive stress on the dielectric layer 220, potentially leading to its fracture.

On the other hand, if the dishing is too deep, the expansion of copper may not overcome the gap between the pads, and copper-to-copper bonding may not be achieved. This dishing varies with the process temperature during the interface formation process. In a high-temperature environment, more expansion of copper occurs, making it easier to overcome a deeper dishing gap.

However, if bonding is performed in a high-temperature environment, oxidation of copper may occur, there is a possibility of copper diffusing into the insulating layer due to misalignment, and the properties of the copper or underlying devices may deteriorate, leading to various reliability issues. Therefore, a low-temperature process environment of 300° C. or below is required.

Furthermore, when bonding is performed in a high-temperature environment, phenomena like warpage and thermal stress may be exacerbated, which further emphasizes the importance of a low-temperature bonding process.

However, at low temperatures, the expansion of copper may not be sufficient, and the level of dishing gap that can be overcome may become very small, which may pose difficulties in controlling dishing.

In addition, when SiO₂ is used as the dielectric, it is vulnerable to copper diffusion, and a temperature of 300° C. or higher must be applied to achieve a bonding strength above the required level, which presents clear limitations in terms of thermal budget and reliability.

In the low-temperature hybrid bonding method according to an embodiment of the present disclosure, a carbon layer, specifically a hydrogenated amorphous carbon layer, is formed on the copper surface by plasma treatment using a hydrocarbon-based gas. This prevents the formation of an oxide layer on the copper surface due to air exposure, thereby reducing the energy barrier required for the diffusion of copper atoms, allowing bonding to be performed at a low temperature of 300° C. or below.

Furthermore, the carbon layer formed on the copper surface is thermally decomposed and transformed during the bonding process to form a uniform bonding interface composed of copper-copper, so a high bonding strength may be achieved even when bonding at a low temperature of 300° C. or below.

In the bonding step of the low-temperature hybrid bonding method according to an embodiment of the present disclosure, the bonding temperature may be 300° C. or below, the bonding time may be 60 minutes or less, and the bonding pressure may be 20 MPa or less. However, the above-mentioned process conditions are merely exemplary, and the process conditions for wafer-to-wafer bonding or chip-to-chip bonding may differ.

In the bonding step, the carbon layer formed on the copper thin film 240 included in the first and second objects to be bonded 310 and 320 is thermally decomposed, and only copper remains at the joint, so that a joint made only of copper may be formed.

In the bonding step, an annealing process may be further performed after bonding, and the annealing may be performed at a temperature of 200° C. to 250° C. for 50 to 120 minutes.

In the low-temperature hybrid bonding method according to an embodiment of the present disclosure, the bonding process may be performed at a low temperature of 300° C. or below because the surfaces of the copper thin film and the dielectric are maintained in an activated state by plasma treatment with a hydrocarbon-based gas.

Furthermore, since a void-free bonding interface that allows for uniform copper diffusion is formed due to the plasma treatment, high bonding properties may be achieved even when the bonding process is conducted at a low temperature.

The low-temperature hybrid bonding method according to an embodiment of the present disclosure is very simple because the activation of the copper and dielectric surfaces may be performed in a single plasma treatment process, making it very easy to apply to semiconductor manufacturing.

In addition, the pre-treatment step, in which the cleaning and activation of the copper and dielectric surfaces are performed by plasma treatment with a hydrocarbon-based gas, may be performed at room temperature. Since no additional materials for bonding, such as bonding paste, are introduced, the bonding process has high reproducibility and is simple.

Moreover, the pre-treatment step, which involves plasma treatment with a hydrocarbon-based gas, and the bonding step, which involves thermo-compression at a low temperature, may be performed as a continuous process in semiconductor manufacturing. This makes the process very simple, and since the joint is composed only of copper, it has the advantage of excellent electrical and thermal conductivity properties.

Therefore, the low-temperature hybrid bonding method according to an embodiment of the present disclosure may be applied not only to the bonding between objects to be bonded that include a hybrid bonding layer of copper and a dielectric, but also to various next-generation heterogeneous integration packaging technologies such as substrate-to-chip and chip-to-chip packaging, 2.5D and 3D wafer or chip stacking packaging technologies, semiconductor flip-chip packaging technologies, and packaging technologies for MEMS devices, and its application field is expected to be expanded.

Hereinafter, the present disclosure will be described in more detail through examples. These examples are for the purpose of illustrating the present disclosure more specifically, and the scope of the present disclosure is not limited by these examples.

### EXAMPLES AND COMPARATIVE EXAMPLES

An 8-inch notched silicon (Si) wafer with a 700 nm thick SiO₂ layer deposited by plasma-enhanced chemical vapor deposition (PECVD) was used. To enhance the adhesion between the silicon wafer and the copper thin film, a 50 nm thick titanium (Ti) adhesion layer was deposited, followed by the deposition of a 1 μm thick copper (Cu) thin film on the Si wafer using DC magnetron sputtering (SRN-110, SORONA, S-Fab@SeoulTech).

The deposition of the copper thin film was performed under conditions of an operating pressure of 5 mTorr, a DC power of 2000 W, and an argon (Ar) gas flow rate of 100 sccm; after the deposition of titanium and copper, C₂H₄ plasma treatment was performed.

In the present disclosure, to optimize the plasma treatment conditions required to prevent re-oxidation of the copper thin film and form a carbon layer that minimizes copper oxides, a Design Of Experiment (DOE) approach based on the Response Surface Method (RSM) was used: the plasma treatment conditions were optimized using a Central Composite Design (CCD) method with three main parameters: ICP power, chamber pressure, and CH₄ flow rate.

Table 1 below shows the Design Of Experiments (DOE) according to various plasma process conditions; the experiments were conducted under constant conditions of RF power (0 W), argon flow rate (30 sccm), process time (60 seconds), chuck temperature (25° C.), chamber temperature (60° C.), and ICP frequency (13.56 MHz).

TABLE 1

| | ICP Power | Working Pressure | Gas flow |
|---|---|---|---|
| Classification | (W) | (mTorr) | (sccm) |
| Case 0 | 0 | 0 | 0 |
| Case 1 | 1150 | 0 | 42.5 |
| Case 2 | 300 | 6 | 42.5 |
| Case 3 | 1150 | 10 | 42.5 |
| Case 4 | 2000 | 10 | 70 |
| Case 5 | 1150 | 3 | 42.5 |
| Case 6 | 1150 | 6 | 42.5 |
| Case 7 | 2000 | 6 | 42.5 |
| Case 8 | 1150 | 6 | 15 |
| Case 9 | 300 | 10 | 70 |
| Case 10 | 2000 | 10 | 15 |
| Case 11 | 300 | 3 | 70 |
| Case 12 | 1150 | 6 | 70 |
| Case 13 | 300 | 10 | 15 |
| Case 14 | 2000 | 3 | 15 |
| Case 15 | 300 | 3 | 15 |
| Case 16 | 2000 | 3.68 | 70 |

A one-stage Design of Experiment (DOE) for parameter screening and optimization of Ar—CH₄ plasma conditions was performed based on X-ray Photoelectron Spectroscopy (XPS) analysis. Quantification of Cu oxides on the Cu surface was performed through deconvolution of the Cu2p_{3/2} peak and the Cu LMM Auger peak, and analysis of the Full Width at Half Maximum (FWHM) of the Cu₂p^{1/2} peak.

Furthermore, to evaluate the surface carbon layer formed by the plasma treatment, deconvolution of the C1s peak and measurement of post-etch C—C residue using XPS depth profiling were performed.

FIG. 4 is a schematic diagram illustrating the chip-level dicing and bonding process after plasma treatment.

As shown in FIG. 4, after performing plasma treatment on the entire wafer surface, bonding samples were prepared by dicing them into chip units using a diamond pen, followed by a bonding process. The bonding process was performed under atmospheric conditions at a pressure of 15 MPa and a temperature of 260° C. for 1 hour, followed by an annealing process at 200° C. for 1 hour after bonding.

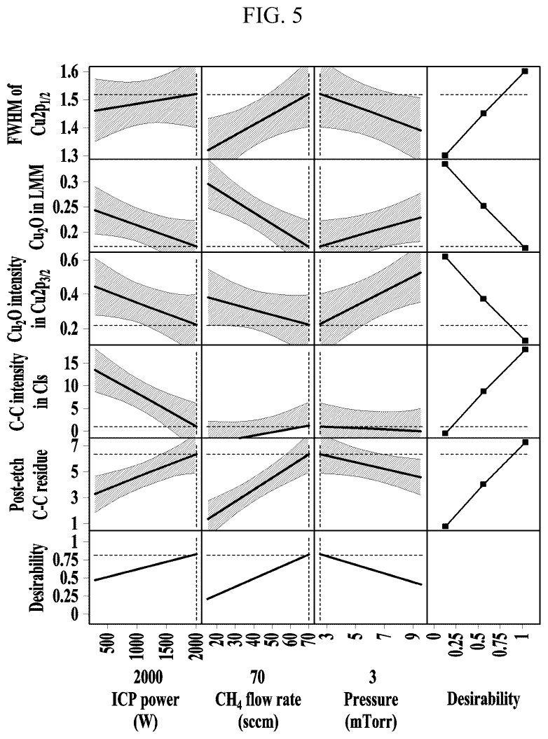

FIG. 5 is a set of graphs illustrating the relationship between input variables and response indicators according to the Design of Experiment (DOE) and Response Surface Method (RSM) performed to optimize plasma treatment conditions according to an embodiment of the present disclosure. In FIG. 5, the gray band represents the prediction confidence interval, the black solid line represents the model prediction trend, and the red dotted vertical lines indicate the selected setting values.

FIG. 5 illustrates response indicators (copper oxide signal intensity (Cu₂O intensity in LMM and Cu₂p^{3/2}), peak width of the copper metallic signal (FWHM of Cu₂p^{1/2}), C—C intensity of the surface carbon layer (C—C intensity in C1s), post-etch carbon residue, and desirability (each row on the vertical axis)) according to the input variables of ICP power (W), CH₄ flow rate (sccm), and pressure (mTorr) (3 columns on the horizontal axis). It can be confirmed that high power, low pressure, and a medium level of CH₄ flow rate are the optimized conditions for low-temperature copper bonding.

More specifically, referring to the indicators for the presence of copper surface oxide (Cu₂O in LMM) and copper surface oxide intensity (Cu₂O intensity in Cu2p_{3/2}) in FIG. 5, the signal intensity of copper oxide tends to decrease as the ICP power increases, the CH₄ flow rate increases, and the pressure decreases.

That is, the reduction reaction of copper surface oxides is promoted as high-density plasma, sufficient hydrogen and carbon radicals are supplied. In particular, under low-pressure conditions, the mean free path becomes longer, increasing the energy of ions upon reaching the surface, which is interpreted as making the removal of the oxide film more effective.

The FWHM of Cu 2p_{1/2}, an indicator of the peak width of the copper metallic signal, narrows as the metallic copper state becomes more dominant. It is confirmed that the metallic property is enhanced as the ICP power increases and the pressure decreases, while the peak width tends to increase if the methane gas (CH₄) flow rate is too low or too high.

The change in the peak width of the copper metallic signal is interpreted as indicating that sufficient ionization and low-pressure acceleration are advantageous for reduction and surface cleaning.

Furthermore, if the amount of methane gas is too little, the reducing power is insufficient, but if the amount of methane gas is too much, an excessive carbon film is formed. Therefore, it is interpreted that at a medium level of methane gas flow rate, the oxide reduction and carbon layer formation are balanced, maintaining the most stable metallic copper state.

The C—C intensity component of the surface carbon layer (C—C intensity in C1s) is an indicator of the thickness of the surface carbon layer and tends to be proportional to the amount of carbon layer formed on the surface.

More specifically, at a low CH₄ flow rate, the carbon layer does not grow sufficiently, resulting in low C—C intensity. However, at a high CH₄ flow rate, carbon accumulation increases, leading to a non-uniform film or increased residue, which tends to increase the C—C intensity. That is, it exhibits a U-shaped pattern, showing the most stable and appropriate thickness at a medium flow rate, while the carbon layer thickness is too thin or excessively increases at its opposite ends.

If the surface carbon layer is too thin, the re-oxidation inhibition effect decreases, and if it is too thick, there is a possibility that the carbon layer will not decompose and remain during copper bonding or that the resistance will increase. Therefore, high ICP power and low-pressure conditions, which suppress excessive carbon accumulation and form a carbon layer of uniform thickness, are considered to be optimal conditions to prevent re-oxidation during bonding while avoiding an increase in electrical resistance due to excessive residual carbon.

The post-etch C—C residue is an indicator of the carbon remaining after pre-treatment and etching. It tends to decrease as the ICP power increases and the pressure decreases, and the carbon residue is minimized under medium CH₄ flow rate conditions.

The optimization trend of post-etch carbon residue is interpreted to be due to the removal of unnecessary polymeric carbon residue under conditions of sufficient ion energy and low pressure, and the phenomenon of excessive carbon residue accumulation when methane gas is in excess.

Finally, desirability is a composite index that considers all the aforementioned response indicators. It represents a compromise point that simultaneously satisfies all desired conditions: a minimal value for oxide-related indicators, a C—C intensity close to the target value, and a small amount of residue.

In the present disclosure, it can be confirmed that desirability is greatest when the ICP power is increased to the 2000 W level, the CH₄ flow rate is set to about 70 sccm, and the pressure is lowered to about 3 mTorr.

This condition simultaneously satisfies the requirements where the reduction of copper surface oxides proceeds effectively to maintain metallic properties stably, a carbon layer of uniform thickness is formed, and excessive carbon residue is suppressed.

Furthermore, under this condition, the copper surface is preserved in a state where re-oxidation is suppressed, and the occurrence of electrical resistance or interfacial defects due to residual carbon during bonding is prevented, allowing for the formation of a uniform and reliable copper-copper bonding interface even at a low temperature of 300° C. or below.

Therefore, FIG. 5 shows that an optimal condition satisfying multiple response indicators simultaneously may be derived, and indicates that the derived condition is the most suitable pre-treatment condition for the low-temperature hybrid bonding process of the present disclosure.

Table 2 below shows the effect of each input variable and interaction term on the response indicators, based on the results of FIG. 5. Table 2 shows the statistical significance of the effects of methane flow rate (sccm), inductively coupled plasma power (W), pressure (mTorr), and the interactions of these variables on the response indicators, expressed as Log worth and P-value.

As shown in Table 2, the methane (CH₄) flow rate has the largest single variable effect (P=0.00253), indicating that controlling the gas supply rate is the most critical factor in the copper oxide reduction reaction and surface carbon layer formation.

ICP power also acts as the second largest influencing factor (P=0.01170), confirming that it increases the ionization density in the plasma and contributes to the removal of oxides and activation of the copper surface.

Furthermore, the interaction (P=0.01614) between pressure and CH₄ flow rate, the interaction (P=0.01774) between ICP power and pressure, and the interaction (P=0.02511) between ICP power and CH₄ flow rate are also found to be statistically significant. This is interpreted as meaning that not only single variables but also the combination of variables play an important role in achieving the effects of the present disclosure.

The same trend is confirmed in the DOE results presented in FIG. 5, where the reduction efficiency of copper oxides is most improved under conditions of high ICP power, low pressure, and high CH₄ flow rate. This is directly related to the increase in plasma energy and the density of reactive species, which is interpreted as promoting the generation of hydrogen radicals and carbon radicals, thereby enhancing the reduction of copper oxides.

In the present disclosure, among the 16 DOE conditions, Case 16, which has the highest oxidation-reduction efficiency but forms a relatively large amount of post-etch carbon residue, and Case 11, which has a slightly lower reduction performance but the highest normalized carbon intensity and can represent the characteristics of the surface carbon layer, were selected as final analysis targets. By comparing and analyzing the copper oxide reduction performance and surface carbon layer characteristics, focusing on Cases 11 and 16, the pre-treatment conditions and surface structure suitable for low-temperature copper-copper bonding were identified.

### [Evaluation Method]

To evaluate the effect of plasma treatment on the Cu surface, various surface and interface analysis techniques were utilized, including X-ray Photoelectron Spectroscopy (XPS, Nexsa, Thermo Fisher Scientific Brno s.r.o), Time-of-Flight Secondary Ion Mass Spectrometry (TOF-SIMS, IONTOF GmbH M6), Transmission Electron Microscopy (Cs TEM, NEO ARM/JEOL), and four-point probe measurements.

XPS measurements were performed to evaluate the chemical states and composition produced, with a particular focus on quantifying the degree of Cu oxide reduction and characterizing the sp²/sp³ hybridization structure of the surface carbon layer. To characterize the microstructure and composition of the CₓH_{y} layer on the Cu surface, TOF-SIMS and cross-sectional TEM were performed.

After bonding, the interface morphology was observed using a Field Emission Scanning Electron Microscope (FESEM, JEOL Ltd. (IT800SHL)) and Transmission Electron Microscope (TEM) to confirm the presence of micro-voids and analyze the underlying bonding mechanism. The bonding quality was evaluated by measuring the mechanical shear strength.

A shear test was performed using a multifunctional bonding tester (MFM 1200, DGFT) to compare the mechanical strength of Ar—CH₄ plasma-treated samples and non-plasma-treated samples.

### [Experimental Example 1] Analysis of Plasma-Treated Copper Surface

In the present disclosure, to investigate the sub-surface region of the carbon layer and copper layer after plasma treatment for Case 16 and Case 11, five consecutive etching steps of 5 seconds each were applied, and X-ray photoelectron spectroscopy analysis was conducted. The X-ray photoelectron spectroscopy analysis was performed using an Al Kα source (1486.6 eV).

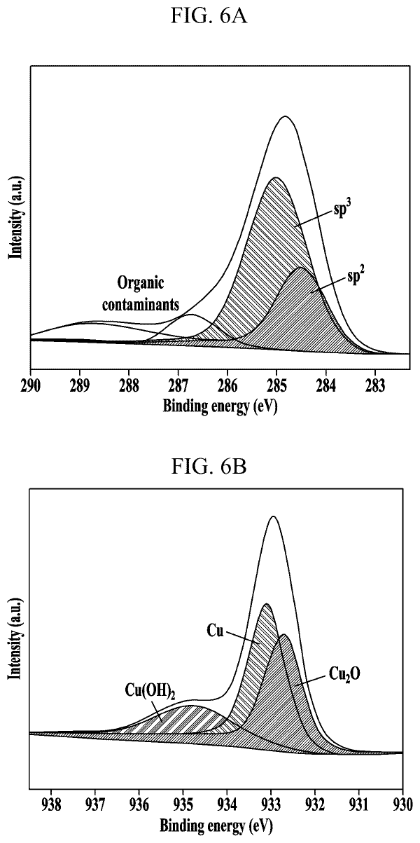

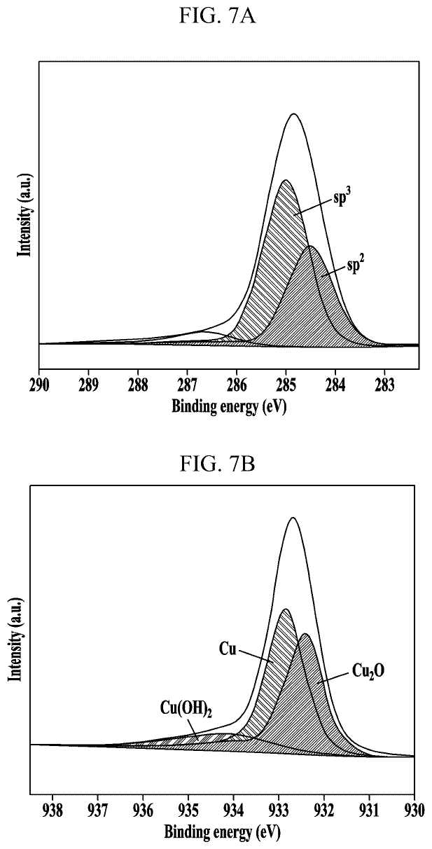

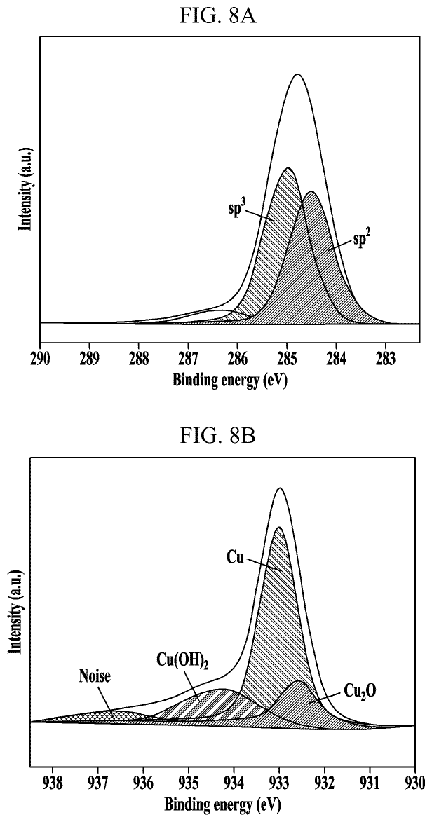

FIGS. 6A to 8B illustrate the peak deconvolution results of C1s(a) and Cu₂p^{3/2}(b) for a non-plasma sample, Case 11, and Case 16, respectively, and Table 3 below shows the peak deconvolution binding energies for Cu2p_{3/2} and C1s.

TABLE 3

| | | C1s | | | | | | |
|---|---|---|---|---|---|---|---|---|
| | | C—C | C—C | | | Cu2p_{3/2} | | |
| Peak | | (sp²) | (sp³) | C—O | C═O | Cu₂0 | Cu0 | Cu(OH)₂ |
| Binding | Non-plasma | 284.5 | 285 | 286.3 | 288.5 | 932.7 | 933.1 | 934.77 |
| energy | Case 11 | 284.5 | 285 | 286.3 | 287.8 | 932.85 | 932.45 | 934.3 |
| (eV) | Case 16 | 284.5 | 285 | 286.3 | 287.8 | 932.6 | 933 | 934.3 |

Referring to FIGS. 6A to 8B and Table 3, in the non-plasma condition without plasma treatment, oxidative carbon species such as C═O (288.5 eV) and organic contaminants are strongly present, indicating a state of severe surface contamination and oxidation.

Furthermore, in the Cu2p_{3/2} spectrum of the non-plasma condition, the Cu₂O (932.7 eV) and Cu(OH)₂ (934.77 eV) peaks are distinct, confirming the presence of a thick oxide film and hydroxides.

In contrast, in Cases 11 and 16, the C═O peak intensity decreases to 287.8 eV, and the sp² and sp³ peaks are clearly distinguished, confirming that surface contamination is removed by the plasma treatment and that the carbon is formed as an amorphous carbon film with a mixed sp² and sp³ bonding structure, rather than as contaminants. Particularly in the Case 16 condition, the sp² and sp³ components are balanced, which is interpreted as the formation of a stable carbon layer.

Furthermore, comparing the Cu2p_{3/2} spectra, the Cu₂O (932.7 eV) and Cu(OH)₂ (934.77 eV) peaks are distinct in the non-plasma condition, indicating the presence of a thick surface oxide layer.

However, in both Cases 11 and 16, the intensities of the Cu₂O and Cu(OH)₂ peaks decrease, and the metallic Cu peak is enhanced, showing that copper oxides are effectively reduced and metallicity is restored by the plasma treatment. Particularly in the Case 16 condition, the metallic Cu peak is the strongest, indicating that the oxide film removal was most effective.

Also, while the main surface peak before etching was located between the binding energies of Cu⁰ and Cu₂O, a significant decrease in Cu₂O and a corresponding increase in Cu0 were detected in Case 16 after Ar—CH₄ plasma treatment, showing that hydrogen radicals and ions generated under high-power and low-pressure conditions effectively reduced the Cu oxides.

In contrast, in Case 11, which is a low-power condition, a distinct oxide reduction was not observed, confirming that the role of hydrogen ions is crucial for copper oxide reduction.

In addition, an OH peak was additionally observed in Case 16. Unlike the Cu(OH)₂ detected in the non-plasma condition, this additional OH peak is attributed to the surface activation effect by the Ar—CH₄ plasma, suggesting that the copper surface became hydrophilic after plasma treatment. On the other hand, such an OH peak was not observed in Case 11, indicating that surface activation did not occur sufficiently under the conditions corresponding to Case 11.

Therefore, FIGS. 6A to 8B and Table 3 show that, compared to the non-plasma condition, the Case 16 condition most effectively achieves the removal of copper oxides and restoration of metallicity, while simultaneously forming a uniform amorphous carbon layer and securing surface hydrophilicity. Thus, this is interpreted as a result demonstrating that the Case 16 condition is the most suitable pre-treatment condition for low-temperature copper-copper bonding.

Table 4 below shows the results of measuring the composition of the copper surface layer before and after plasma treatment using Time-of-Flight Secondary Ion Mass Spectrometry (TOF-SIMS). Table 4 shows the ratios of hydrogen anion (H—) and carbon-based fragments (C—, CH—, CH₂—, C₂H—, C₃H—, C₃H₂—, C₄H—) detected under the conditions of non-plasma, Case 11, and Case 16.

TABLE 4

| Classification | | Non-plasma | Case 11 | Case 16 |
|---|---|---|---|---|
| Area/Total Area | H⁻ | 17.82% | 67.63% | 69.70% |
| | C⁻ | 1.09% | 2.60% | 2.65% |
| | CH⁻ | 2.51% | 8.85% | 8.85% |
| | CH₂⁻ | 0.32% | 1.48% | 1.32% |
| | C₂H⁻ | 3.52% | 6.47% | 6.18% |
| | C₃H⁻ | 0.16% | 0.21% | 0.18% |
| | C₃H₂⁻ | 0.12% | 0.27% | 0.21% |
| | C₄H⁻ | 0.56% | 0.38% | 0.31% |

As shown in Table 4, in the non-plasma condition without plasma treatment, the detection ratio of hydrogen and hydrocarbon-related ions is low, indicating that the surface is covered with organic contaminants and an oxide film.

In contrast, in Cases 11 and 16, the ratios of H—, CH—, CH₂—, C₂H—, etc., are significantly increased, confirming that a hydrogenated amorphous carbon layer (a-C:H layer) was formed on the copper surface during the Ar—CH₄ plasma treatment process.

The increase in the ratio of hydrogen ions and carbon fragments after plasma treatment is consistent with the results from the C1s spectra in FIGS. 6A to 8B and Table 3, where the C═O component decreased and the sp² and sp³ peaks appeared distinctly, suggesting that surface contamination is removed and a hydrogenated carbon layer is stably deposited through plasma treatment.

Furthermore, in Case 16, the carbon layer formed under high ICP power and low-pressure conditions contains a relatively high sp² component, which means that the hydrogen incorporation amount and the sp²/sp³ ratio may vary depending on the plasma conditions.

An a-C:H layer with high hydrogen content provides mechanical ductility, and a layer with a high sp² component improves electrical conductivity. Therefore, it is interpreted that optimizing the sp²/sp³ ratio and hydrogen content by adjusting the plasma conditions is an important factor in optimizing the low-temperature bonding process.

Therefore, Table 4 shows that the component distribution of the a-C:H layer varies with plasma conditions, which directly affects the mechanical stability and electrical properties of the interface. Consequently, the results of Table 4 show that by simultaneously removing copper oxides and forming a uniform and stable a-C:H protective layer, a reliable copper-copper bonding interface may be realized even at a low temperature of 300° C. or below.

### [Experimental Example 2] Investigation of Microstructure of Copper Surface and Electrical Properties of Hydrogenated Amorphous Carbon Layer (a-C:H Layer)

### 1) Investigation of Microstructure of Copper Surface

The microstructure of the Cu surface before and after Ar—CH₄ plasma treatment was investigated using Transmission Electron Microscopy (TEM) and Fast Fourier Transform (FFT) analysis.

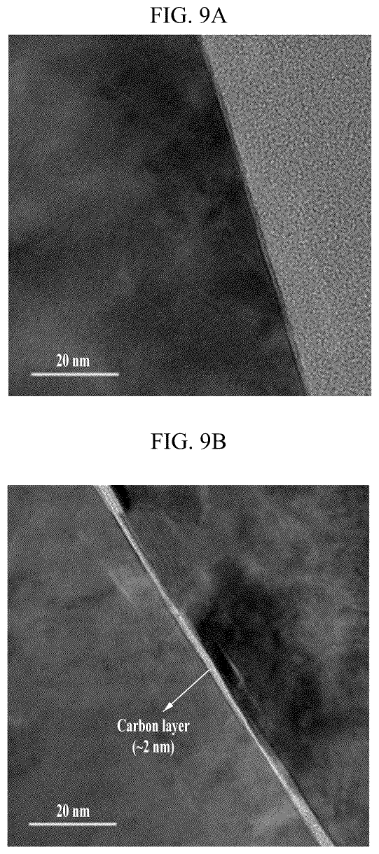

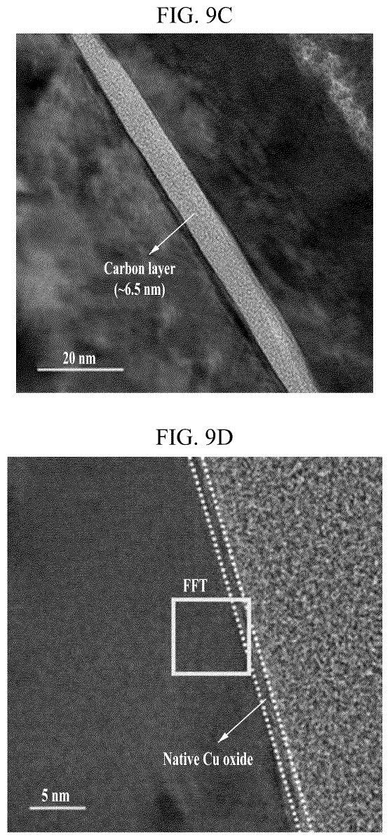

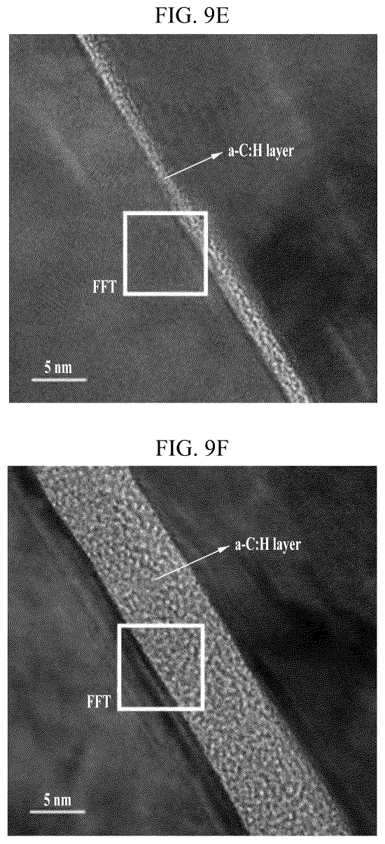

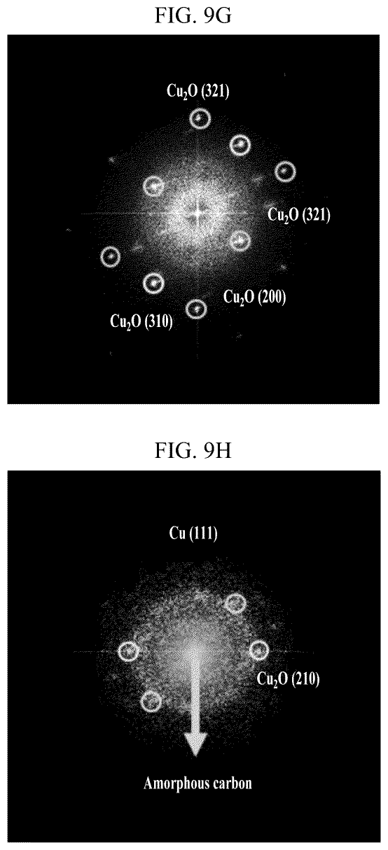

FIGS. 9A to 9F are cross-sectional TEM images comparing the surface carbon layers of the non-plasma sample (Case 0; a, d), Case 11 (b, e), and Case 16 (c, f), and FIGS. 9G to 9I illustrate the FFT patterns of the non-plasma sample (Case 0), Case 11, and Case 16, respectively.

FIGS. 9A and 9D illustrate the cross-section under the non-plasma condition (Case 0), where a native Cu oxide film of about 1-2 nm thickness is confirmed to be formed on the copper surface. Furthermore, in the FFT pattern of the non-plasma condition (FIG. 9G), diffraction spots corresponding to the Cu₂O (321, 310, 200) planes are clearly observed, indicating that an oxide film is present across the entire surface.

FIGS. 9B and 9E illustrate the cross-section for Case 11, where it is confirmed that a porous carbon layer (a-C:H layer) of about 2 nm thickness is deposited on the copper surface. However, in the FFT pattern for Case 11 (FIG. 9H), the Cu₂O (210) peak is still observed, confirming that the reduction of copper oxides was incomplete and that oxides remain beneath the surface. In the case of Case 11, the residual oxide is interpreted as a cause for hindering the continuous formation of the carbon layer, thereby reducing the carbon coverage.

FIGS. 9C and 9F illustrate cross-sections under high-power and low-pressure conditions (Case 16), where it is confirmed that a uniform and continuous carbon layer (a-C:H layer) of about 6.5 nm thickness is formed over the entire copper surface. Furthermore, in the FFT pattern of Case 16 (FIG. 9I), while the Cu(111) and Cu(110) diffraction spots appear clearly, any detectable Cu₂O peaks have disappeared, and an amorphous carbon distribution is confirmed, indicating that the oxide film removal was effectively achieved.

Therefore, according to FIGS. 9A-9I, in the case without plasma treatment (Case 0), a thick oxide film is present, and in Case 11, the oxide reduction is incomplete although a carbon layer is formed, resulting in the presence of residual oxides.

In contrast, under the high-power and low-pressure condition (Case 16), the oxides are completely removed, and a uniform hydrogenated amorphous carbon layer is formed on the smooth copper surface, confirming that oxide removal and protective layer formation are achieved simultaneously. That is, the Case 16 condition is interpreted as the optimized pre-treatment condition for low-temperature copper-copper bonding.

### 2) Investigation of Electrical Properties of Hydrogenated Amorphous Carbon Layer (a-C:H Layer)

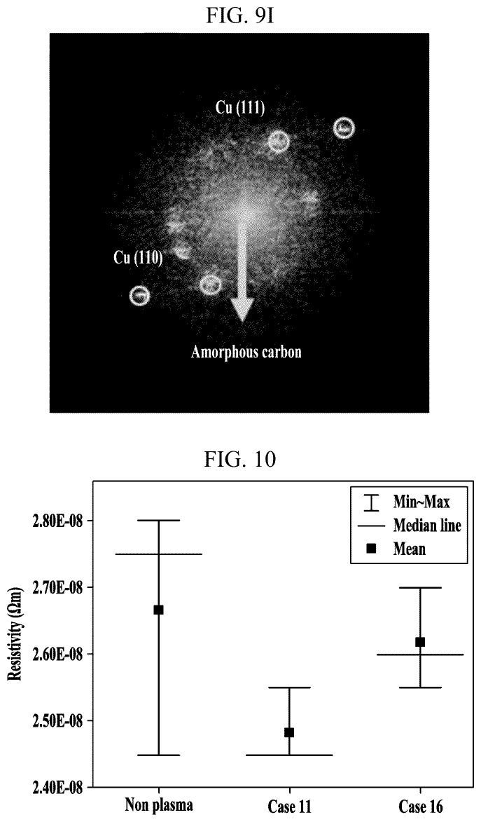

FIG. 10 is a graph comparing the resistivity of the copper thin films according to the presence and conditions of plasma treatment. FIG. 10 shows the resistivity for a non-plasma condition, Case 11, and Case 16, respectively, and indicates the mean (▪), median line, and min-max range for each condition.

As shown in FIG. 10, in the non-plasma condition, the average resistivity is the highest at about 2.7E-08 Ωcm, and the measurement distribution is wide, indicating significant electrical non-uniformity due to the surface oxide film and contaminants.

In contrast, Case 11 measured the lowest resistivity at about 2.5E-08 Ωcm, which is interpreted as a result of the formation of a thin and soft hydrogenated amorphous carbon layer (a-C:H layer) and a decrease in oxides due to plasma treatment, leading to the stabilization of copper's conductive properties.

In Case 16, a resistivity of about 2.6E-08 Ωcm was confirmed. The resistivity of Case 16 is similar to the resistivity of thin copper films reported in the literature, which means that the oxides were completely removed, and conductivity was secured. However, it is considered that the resistivity in Case 16 is slightly increased compared to Case 11 due to the formation of a thicker a-C:H layer.

Therefore, the results of FIG. 10 show that by removing the copper surface oxide film and forming a uniform a-C:H layer through plasma treatment, superior conductivity may be secured compared to the non-plasma condition.

Furthermore, since the thickness and hydrogen content of the carbon layer directly affect the electrical properties of the copper thin film, it is understood that optimizing the balance between oxide removal and securing electrical conductivity is essential for the low-temperature copper bonding process.

### [Experimental Example 3] Investigation of Bonding Interface Characteristics

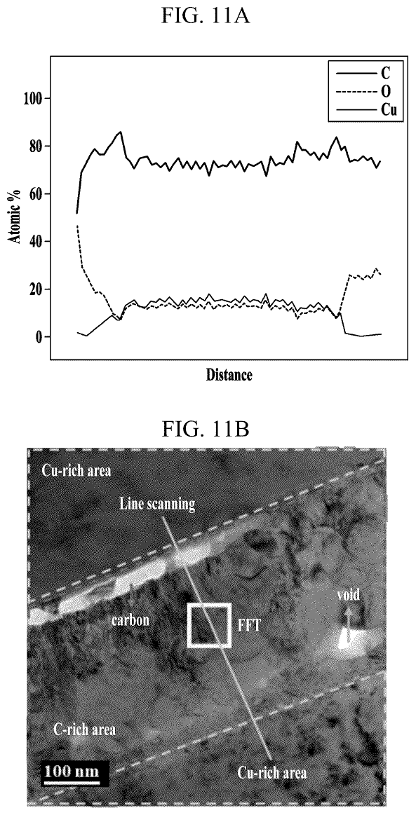

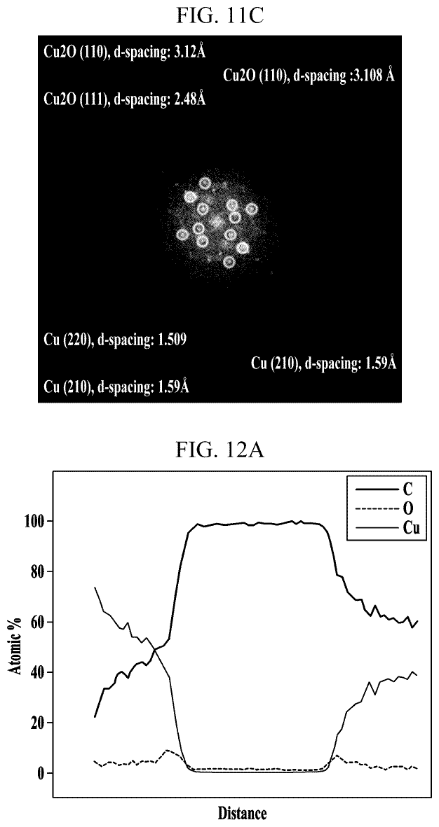

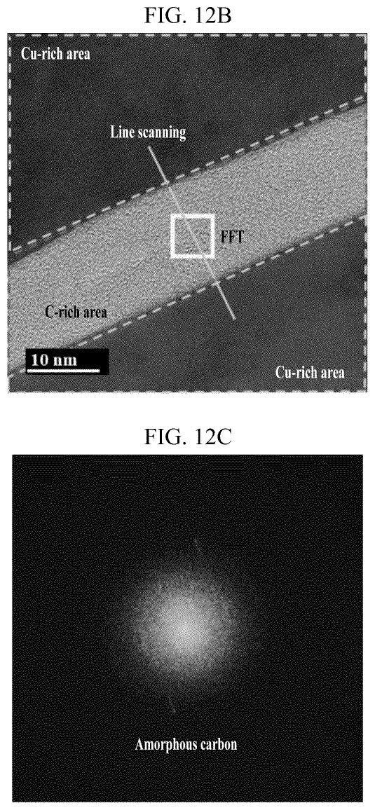

FIGS. 11A to 12C illustrate the line scanning results (a), a cross-sectional TEM image of the bonding interface (b), and the FFT analysis results of the bonding interface (c), for Cases 11 and 16, respectively.

As shown in FIG. 11A, in the case of Case 11, it can be seen that the concentration distributions of carbon (C), oxygen (O), and copper (Cu) are non-uniform. Referring to FIG. 11B, it is difficult to identify a clear bonding interface between the Cu-rich area and the C-rich area, and several voids and carbon clusters are observed at the interface.

Furthermore, as shown in FIG. 11C, in the case of Case 11, Cu₂O (110, 111), Cu₂O (210), and Cu (220, 210) peaks are observed, indicating that copper oxides remain beneath the bonding interface.

The results of FIGS. 11A to 11C show that the plasma conditions were not strong enough, leading to incomplete oxide reduction. The residual oxides hinder the formation of a uniform carbon layer (a-C:H layer), resulting in a discontinuous carbon layer and voids, which degrades the bonding reliability.

In contrast, in the line scanning results of Case 16 under high-power conditions shown in FIG. 12A, the boundary between the carbon layer and the copper layer is clearly distinguished, and the distributions of carbon and copper are observed to be distinctly partitioned.

Furthermore, as shown in the cross-sectional TEM image of FIG. 12B, it is confirmed that a continuous and uniform hydrogenated amorphous carbon layer (a-C:H layer) is formed between the Cu-rich area and the C-rich area.

Also, according to the FFT analysis results in FIG. 12C, diffraction spots of copper (Cu 111, Cu 210) are observed, but copper oxide (Cu₂O) peaks are not detected, and a distinct amorphous carbon distribution is confirmed, indicating that the oxide film was effectively removed by the plasma treatment.

Furthermore, referring to FIG. 12A, the carbon signal is strong in the a-C:H layer and should decrease as it moves into the copper layer. However, it is confirmed that the carbon signal is maintained at a certain level even in the copper bulk side where the copper signal increases. The maintenance of the carbon signal even in the copper bulk side is interpreted as the diffusion of carbon into the copper bulk.

However, as shown in the FFT analysis results of FIG. 12C, thermodynamically unstable Cu—C compounds are not detected, so the concern of electrical or mechanical degradation due to Cu—C compound formation is interpreted to be low.

Therefore, it is confirmed that the a-C:H layer formed by the plasma pre-treatment under the Case 16 condition functions as a diffusion barrier to suppress re-oxidation before bonding and is continuously formed on the reduced metallic copper surface to provide a stable bonding interface.

Additionally, as a result of the shear strength evaluation, the non-plasma condition showed an average strength of 17.0 MPa, whereas Case 16 showed a high average strength of 25.0 MPa. This is interpreted as an improvement in bonding strength due to the securing of oxide removal and interfacial continuity by the plasma pre-treatment.

Thus, through the results of FIGS. 11A to 12C, it is confirmed that pre-treatment under high-power and low-pressure conditions provides a suitable interface for low-temperature copper-copper bonding and realizes a reliable bond by utilizing the limited bulk diffusion of carbon.

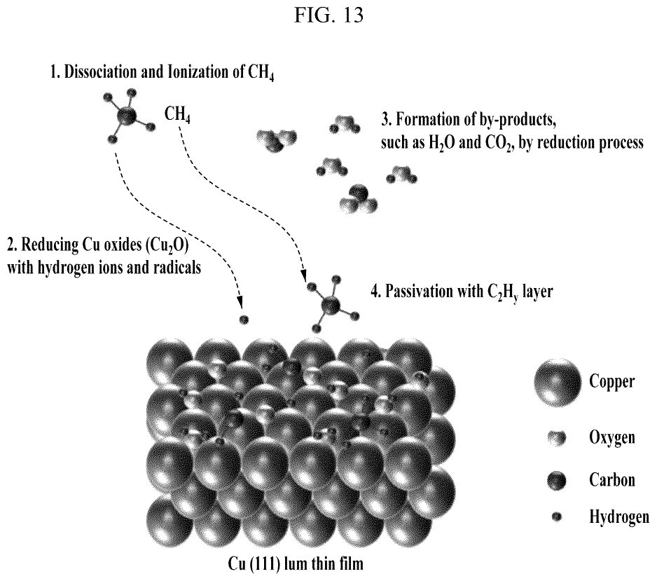

FIG. 13 illustrates the Ar—CH₄ plasma treatment mechanism of the present disclosure. FIG. 13 sequentially illustrates reaction pathways that occur during the plasma treatment process.

First, methane molecules (CH₄) are dissociated and ionized by the plasma (Dissociation and Ionization of CH₄), generating various reactive species such as hydrogen ions (H⁺), hydrogen radicals (H·), and carbon radicals (C·). Table 5 below shows the reactive species generated by the plasma.

TABLE 5

| Ions | Radicals | Molecules |
|---|---|---|
| H⁺, H₂⁺, CH⁺, CH₂⁺, CH₃⁺, | H, CH, CH₂, CH₃, | H₂, CH₄, C₂H₂, |
| C₂H⁺, C₂H₂⁺, C₂H₅⁺, C₃H⁺, | C₂H₃, C₂H₅ | C₂H₄, C₃H₈ |
| C₃H₂⁺, C₄H⁺ | | |

Subsequently, the generated hydrogen ions and radicals reduce the copper oxides (Cu₂O), removing the oxides present on the copper surface. In this process, by-products such as H₂O and CO₂ are generated (Formation of by-products, such as H₂O and CO₂, by reduction process). Finally, on the reduced copper surface, hydrogenated carbon species are deposited and coated as a CₓH_{y} layer (Passivation with CₓH_{y} layer), which functions as a diffusion barrier to suppress re-oxidation.

As shown in FIG. 13, the concentration of generated hydrogen ions and radicals varies depending on the plasma power and pressure conditions. Under higher power and lower pressure conditions, the generation of hydrogen ions increases, leading to more effective oxide reduction.

Furthermore, as the methane (CH₄) flow rate increases, the residence time of gas molecules is shortened, allowing for the swift removal of by-products, which improves the efficiency of the reduction reaction.

Through the reaction pathway in FIG. 13, a uniform hydrogenated amorphous carbon (a-C:H) layer is formed on the copper surface where reduction has been completed. This formed hydrogenated amorphous carbon layer suppresses the re-oxidation of copper before and after the bonding process, providing a stable and reliable bonding interface even at low temperatures.

As such, FIG. 13 indicates that the plasma treatment mechanism proceeds through a chain process of 1) dissociation and ionization of CH₄, 2) reduction of oxides by hydrogen species, 3) removal of reduction by-products, and 4) passivation with a CₓH_{y} layer. It suggests that by controlling the process conditions, a uniform a-C:H layer may be formed, and oxide removal and re-oxidation prevention may be achieved simultaneously.

The low-temperature hybrid bonding method of the present disclosure uses plasma treatment with a hydrocarbon-based gas to reduce oxides on the copper surface and create a carbon layer on the copper surface, which can prevent oxidation reactions on the copper surface until bonding. Furthermore, it has the advantage of good bonding properties without the need to introduce additional materials for bonding, such as a bonding paste.

Also, in the low-temperature hybrid bonding method of the present disclosure, the carbon layer on the copper surface is removed during the bonding process, forming a joint composed solely of copper, which can result in high electrical and thermal conductivity characteristics.

In addition, the low-temperature hybrid bonding method of the present disclosure can improve bonding properties by mitigating the surface roughness of the dielectric surface and enhancing its hydrophilicity through plasma treatment using a hydrocarbon-based gas.

Moreover, the low-temperature hybrid bonding method of the present disclosure can simplify the pre-treatment process for the bonding process, as it can perform surface cleaning and activation for the hybrid bonding layer, including copper and a dielectric layer, in a single process through plasma treatment.

Furthermore, in the low-temperature hybrid bonding method of the present disclosure, the pre-treatment process, where cleaning and activation of the copper and dielectric surfaces are performed using plasma treatment with a hydrocarbon-based gas, can be carried out at room temperature. This allows it to be utilized for stacked bonding of packaging devices with various materials, thereby expanding its range of applications.

Although the present disclosure has been described through limited examples and drawings, the present disclosure is not intended to be limited to the examples. Those skilled in the art will appreciate that various modifications, additions and substitutions are possible, without departing from the scope and spirit of the disclosure. Therefore, the scope of the present disclosure should not be limited to the described examples, but should be defined not only by the claims described below but also by equivalents of these claims.

[Description of Symbols]

| | |
|---|---|
| 210: substrate | 220: dielectric layer |
| 230: metal layer | 240: copper thin film |
| 310: first object to be bonded | 320: second object to be bonded |

What is claimed is:

1. A low-temperature hybrid bonding method, comprising:
a pre-treatment step of plasma-treating surfaces of first and second objects to be bonded; and
a bonding step of aligning the first and second objects to be bonded and annealing them to form a bond between the first object to be bonded and the second object to be bonded through thermal expansion,
wherein the first and second objects to be bonded comprise a hybrid bonding layer comprising copper and a dielectric, and
the pre-treatment step is performed by treating with plasma using a hydrocarbon-based gas (CₓH_{y}, where x and y are natural numbers).

2. The low-temperature hybrid bonding method according to claim 1, wherein the hydrocarbon-based gas is one selected from the group consisting of methane (CH₄), methylene (CH₂), acetylene (C₂H₂), ethylene (C₂H₄), and propylene (C₃H₆).

3. The low-temperature hybrid bonding method according to claim 1, wherein the pre-treatment step reduces oxides formed on a surface of the copper comprised in the first and second objects to be bonded, and deposits a hydrogenated amorphous carbon layer (a-C:H layer) with a thickness of 2 to 10 nm on the copper surface to prevent immediate re-oxidation.

4. The low-temperature hybrid bonding method according to claim 1, wherein after the pre-treatment step, surface hydrophilicity of the first and second objects to be bonded is increased, thereby improving interfacial bonding stability, and
surface roughness of the first and second objects to be bonded is reduced, forming a void-free bonding interface that enables uniform diffusion of the copper.

5. The low-temperature hybrid bonding method according to claim 3, wherein the hydrogenated amorphous carbon layer prevents formation of an oxide layer on the copper surface, thereby reducing an energy barrier required for diffusion of copper atoms, and is thermally decomposed during the bonding step to form a copper-copper metal contact surface, thereby enabling bonding to be performed at a temperature condition of 300° C. or below.
